(19) United States
(12) Patent Application Publication
(10) Pub. No.: US 2014/0285216 A1
(43) Pub. Date: Sep. 25, 2014

(54) SYSTEM FOR ENHANCING SIGNAL QUALITY FROM CAPACITIVE BIOMETRIC SENSOR IN A VEHICLE FOR CONTINUOUS BIOMETRIC MONITORING

(71) Applicant: FORD GLOBAL TECHNOLOGIES, LLC, Dearborn, MI (US)

(72) Inventors: Mark A. Cuddihy, New Boston, MI (US); Manoharprasad K. Rao, Novi, MI (US); Jialiang Le, Canton, MI (US)

(73) Assignee: FORD GLOBAL TECHNOLOGIES, LLC, Dearborn, MI (US)

(21) Appl. No.: 13/847,109

(22) Filed: Mar. 19, 2013

(51) Int. Cl. G01R 27/26

(52) U.S. Cl. CPC G01R 27/2605
USPC 324/658

(57) ABSTRACT

A system may include at least one sensor configured to detect at least one vital signal, wherein the sensor is positioned proximate to a driver within a vehicle seat. At least one contact element may be configured to detect at least one reference signal, wherein the contact element surrounds a vehicle steering wheel. At least one resistor may be coupled to the at least one sensor and configured to receive the reference signal from the contact element.

### BACKGROUND

Several systems have been developed for monitoring the biometric data related to a driver in a vehicle. These systems may be used for driver identification, health monitoring, etc. Such biometric data may include a driver's heart rate. This data may be used to make accommodations within the vehicle such as increased break sensitivity, temperature adjustments, and so on. However, an electronic signal representing a driver's biometric data may be susceptible to various environmental variables. Thus, the data may not be accurate and accommodations may be unnecessarily or inappropriately made in view of the inaccurate data.

### SUMMARY

In one embodiment a system may include at least one sensor configured to detect at least one vital signal, wherein the sensor is positioned proximate to a driver within a vehicle seat. At least one contact element may be configured to detect at least one reference signal, wherein the contact element surrounds a vehicle steering wheel. At least one resistor may be coupled to the at least one capacitive sensor and configured to receive the reference signal from the contact element.

A sensor module may include a plurality of capacitive sensors configured to detect at least one vital signal, wherein the sensors are positioned proximate to a driver within a vehicle seat. A resistor may be coupled to each of the sensors and configured to receive a reference signal transmitted from a contact element having direct contact with the driver.

### BRIEF DESCRIPTION

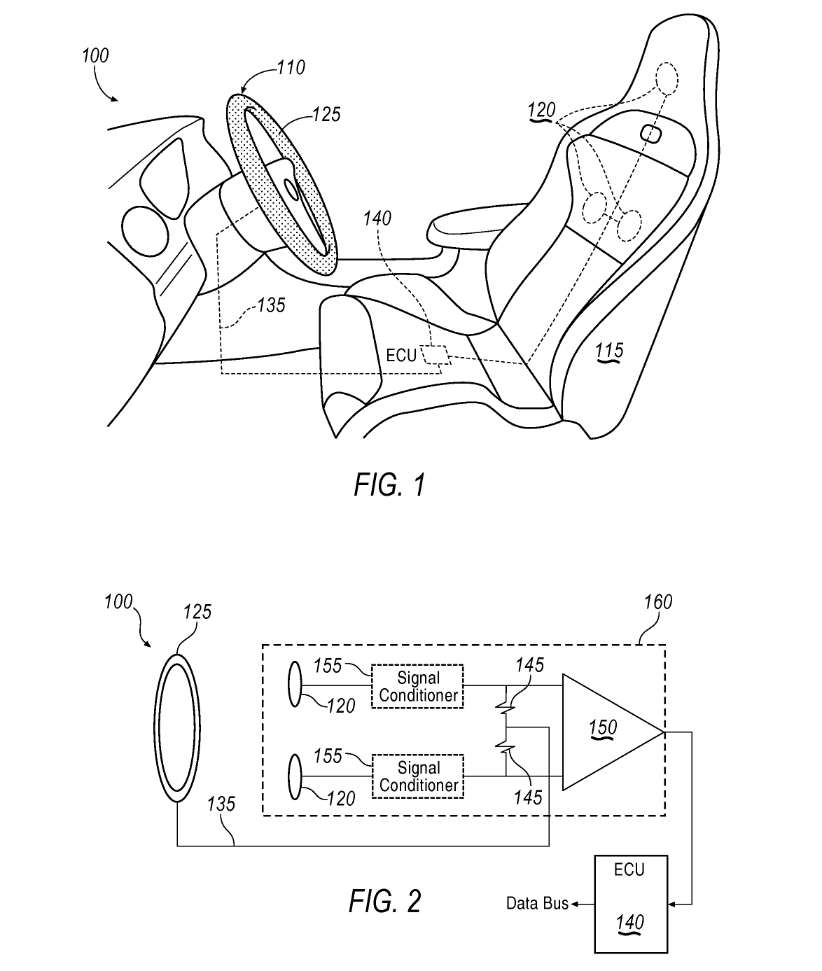

FIG. 1 is an exemplary biometric monitoring system within a vehicle;

FIG. 2 is an exemplary schematic for the biometric monitoring system; and

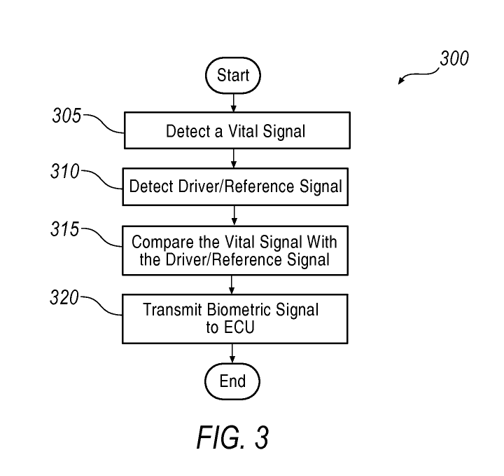

FIG. 3 is an exemplary process for the biometric monitoring system.

### DETAILED DESCRIPTION

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Disclosed herein is a system configured to increase the signal quality of vital signals received from capacitive sensors located within the seat of a vehicle. These sensors may sense electric impulses from the driver. These signals may be used by a control unit to make certain adjustments to vehicle systems based on the perceived physiological status of the driver. For example, if the driver is tired, the temperature within the vehicle may be lowered so as to further alert the driver. However, these signals produced by the sensors are often subject to various environmental variables. For example, the amount of water vapor in the air and the static electricity caused by a driver's clothing may skew the signals from the sensors. Traditional systems may make up for these environmental variables by including a ‘dummy’ sensor within the vehicle. These sensors may include a mat within the seat that acts as a ‘floating ground’. This mat, however, is not in direct contact with the driver and does not accommodate for the driver's electric potential or static within the driver's clothing, etc. Some direct contact systems for monitoring a driver's vital signals may use electrical sensors on the vehicle steering wheel. However, this system requires active participation from the user at least because each of the user's hands must be placed simultaneously at predefined locations.

The disclosed system provides for a user-friendly system for acquiring robust and clean signals for biometric monitoring. The driver may not be aware that such biometric data is being acquired at least because only a single point of contact along any location on the steering wheel may be used to acquire a reference signal from the driver.

Referring to FIG. 1, an exemplary biometric monitoring system 100 is shown. The system 100 may be included as part of a motor vehicle and may include a steering wheel 110 and a vehicle seat 115. The seat 115 may be a driver's seat, as shown in FIG. 1. The seat 115 may include a plurality of sensors 120. These sensors 120 may be capacitive sensors configured to detect vital signs of the driver. For example, the sensors may be configured to detect electrical impulses from the body of the driver. These electric impulses may be transmitted by the driver's brain and indicative of the pulse or heart rate of the driver. Other vital signs may include respiration rate, various brain waves, body part position or displacement, etc. For exemplary purposes only, the vital signs may be discussed herein as including electric impulses indicative of a person's pulse or heart rate.

The sensors 120 may be capable of sensing vital signs without direct contact with the driver to produce a vital signal. For example, the sensors 120 may be arranged in the seat 115 under at least one layer of material. That is, the seat material, such as leather, may cover the sensors 120. The sensors 120 may be arranged at any number of locations within the seat 115, such as within the seat back and/or headrest. The sensors 120 may be arranged within the padding of the seat 115 and covered by the seat material. Thus, the sensors 120 are not noticeable or detectable by the driver. Regardless, the sensors 120 may detect minute changes in an electric field around them. The sensors 120 may therefore be capable of detecting very small disturbances, such as those created by the electrical impulses from the brain which trigger a heartbeat. When a driver sits in the seat 115, the electric field surrounding the driver may be detected, as well as the impulses from the driver's brain.

As explained, the sensors 120 may be capacitive sensors. Additionally or alternatively, other non-contact sensors may be used. In one example, Electric Potential Sensors (EPS) may be used to detect the vital signs of the driver. These sensors are active, ultra-high input impedance sensors. These sensors cause no significant perturbation of the ambient electrical field and are capable of accurately measuring electrical fields.

The sensors 120, as explained, may be placed in multiple locations within the seat 115. In the event that the driver is not in contact with one of the sensors 120, another sensor 120 may still transmit a vital signal. As explained above, while the sensors 120 may detect certain vital signals for the driver, the signals may be subject to various environmental factors such as the driver's own electric potential, as well as static potential in the driver's clothing. Moreover, if the driver touches a grounded component within the vehicle, the sudden discharge of any electric potential may skew the vital signal. In practice, while a user is driving a vehicle, several layers of fabric and material may be between the driver and the sensors 120 (e.g., clothes that the driver is wearing such as sweaters, coats, etc., and layers within the seat itself). These materials may increase the electric potential of the driver and skew the vital signal of the sensors 120. Thus, it is important that a reference signal be present to remove the driver's electric potential from the vital signal.

The steering wheel 110 may include a contact element 125. The contact element 125 may surround the entire steering wheel 110 and be configured to detect a driver signal from the driver at the steering wheel 110. The driver signal may include the electric potential of the driver. The driver signal may also include other biometric data, such as a pulse. The contact element 125 may include a conductive material and be capable of detecting resistance from a driver as the driver places one or more hands on the steering wheel 110. The conductive material may surround the steering wheel 110 and come into direct contact with the driver. Thus, the conductive material may be durable, as well as have an appealing appearance and texture. The material may be capable of withstanding moisture and other environmental wears typically placed on the surface of a steering wheel 110. The material may have a low enough resistance to be capable of detecting the driver signal from the driver. For example, the conductive material may be conductively treated leather, wherein natural leather, or man-made leather-like materials are treated to be conductive. In other example, the material may be a conductive plastic or fabric. Moreover, the conductive material may maintain its conductive properties over time as well as over varying temperatures. That is, the conductive material may be stable regardless of external environments.

As explained, the contact element 125 may surround the entire steering wheel 110 and thus be capable of receiving biometric input from the driver regardless of the driver's hand position on the wheel 110. Thus, regardless of whether the driver is driving with both hands or one hand, a driver signal may be acquired. The contact element 125 may be attached to the wheel 110 via several mechanisms. In one example, the contact element 125 may be sewed on or bonded to the existing steering wheel surface.

A wire 135 may be connected to the contact element 125. The connection may be maintained by an electronic connection such as a crimp connection via a crimping terminal. Other attachment mechanism may also be used such as conductive gluing, soldering, etc. The wire 135 may be any type of wire capable of transmitting the driver signal from the contact element 125.

The wire 135 may also be in communication with the sensors 120 and an Electronic Control Unit (ECU) 140. The wire 135 may carry the driver signal to a front end of the ECU 140 so that the driver signal may act as a reference signal for the sensors 120, as described below with respect to FIG. 2. The driver signal may act as a reference signal for the sensors 120 to create a voltage for input into an electronic device. The difference between the voltage from one sensor 120, and the voltage from another sensor 120 inverted with reference to a common reference signal or ‘virtual ground’ can be subtracted from each other and amplified to produce a biometric signal. The biometric signal may then be transmitted to the ECU 140 for processing.

The ECU 140 may be configured to receive the driver signal. The ECU 140 may then process the signal and determine the biometric state of the driver based on the signal. The processing may include any number of heuristics to determine the biometric state. For example, the biometric signal may include a respiration rate of 15 beats per minute. The ECU 140 may have a predefined threshold that this respiration rate is considered low and thus determine that the driver is drowsy. Based on this determination, a control response may be determined. The control response may include adjusting sensitivity settings as they relate to the brakes. The response may also include temperature adjustment, lighting adjustments, etc. The ECU 140 may be in communication with various vehicle control systems via a data bus. Accordingly, the ECU 140 may be configured to send messages to the various vehicle control systems in response to the biometric signal determination.

In referring to FIG. 2, a schematic diagram of the biometric monitoring system 100 is described. The system 100 may include a sensor module 160. The sensor module 160 may include the sensors 120, signal conditioners, biasing resistors 145, and an amplifier 150. The sensor module 160 may be connected to the contact element 125 via the wire 135. The sensor module 160 may be isolated from other vehicle circuits in an effort to avoid interference from other electrical devices within the passenger compartment of the vehicle.

As explained above, the sensors 120 and a contact element 125 are each configured to collect signals from the driver. The wire 135 is configured to transmit the reference signal collected at the contact element 125 to the front end of the ECU 140. The reference signal may then be compared with the vital signals from the sensors 120. Prior to this comparison, each vital signal may be conditioned by a signal conditioner 155 to produce a more robust and clean vital signal. The signal conditioner 155 may include any of a number of devices and elements to prepare the vital signal for processing. In one example a filter may be used to process the signal along with an amplifier 150. In other examples, a multiplexer may be used to determine which of a plurality of vital signals to send to the amplifier.

Once the vital signal has been conditioned, the signal may then be received at the amplifier 150. The amplifier 150 may be an operation amplifier configured to amplify the difference between the voltage from one sensor 120 and the voltage from another sensor 120 inverted with reference to a common reference signal or ‘virtual ground’ before it is processed by the ECU 140. The sensors 120 are configured to receive electronic signals from the driver. These signals, however, may be minute, and therefore, may need to be amplified prior to being processed by the ECU 140. Inverting one of the vital signals compared to the reference signal and amplifying the difference between that signal and a non-inverted signal significantly increases the signal strength output compared to amplifying a single sensor signal. Accordingly, the amplifier 150 may produce a biometric signal being hundreds or thousands of times larger than the original vital signal.

At least one biasing resistor 145 may be in communication with the signal conditioners 155 between the signal conditioners 155 and the amplifier 150. The biasing resistors 145 may be configured to couple the conditioned vital signals with the reference signal. As shown in FIG. 2, the reference signal may be delivered between the biasing resistors. Here, the reference signal provides a ‘virtual ground’ for the conditioned vital signals capable of being amplified prior to being received by the ECU 140. The reconciled signals from each of the resistors 145 are then input into the differential inputs of the amplifier, amplifying the difference between one signal and a second signal, which has been inverted from the first with respect to the common reference signal or virtual ground. The amplifier 150 in turn may output the biometric signal for the ECU 140 for further processing and analyzing. By comparing the reference signal against the conditioned vital signals, the signal quality of the sensors 120 is significantly improved. The reference signal from the driver's hand is carried directly from the steering wheel 110 to the sensor module 160. Thus, a signal in direct contact with the driver is compared with a non-contact signal. Accordingly, any electric potential created by the driver may be eliminated from the signal and a cleaner indication of the electrical pulses created by the driver may be realized. Thus, environmental conditions may be taken into consideration while continuously monitoring the vital signs of a driver.

FIG. 3 shows an exemplary process 300 for the biometric monitoring system 100. The process may begin at block 305 where the sensors 120 may detect a vital sign of the driver. As explained, the vital sign may be an electrical impulse within the body of the driver indicative of the driver's pulse. The vital sign may be transmitted from the sensor 120 via a wired vital signal transmitter.

In block 310, a driver signal may be detected at the steering wheel 110 of the vehicle. This signal may in turn be transmitted via a wire electrically coupled to the steering wheel 110 to act as a reference signal to the vital signal.

At block 315, the vital signal and the reference signal may be compared. For example, the reference signal may be subtracted from the vital signal. In this case, the electric potential of the driver may be removed from the vital signal, producing a reconciled signal which is a cleaner and more accurate signal due to the comparison with the reference signal.

At block 320, the reconciled signal is transmitted to the ECU 140. As explained above with respect to FIG. 2, the reconciled signal may be amplified by the amplifier 150 prior to being transmitted to the ECU 140. By using the reference signal taken from direct contact with the driver at the steering wheel 110, the ECU 140 has a strong, clean and accurate signal to process.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

In general, computing systems and/or devices such as the controllers, biometric devices, displays, telematics functions, etc., may employ any of a number of computer operating systems, including, but by no means limited to, versions and/or varieties of the Microsoft Windows® operating system, the Unix operating system (e.g., the Solaris® operating system distributed by Oracle Corporation of Redwood Shores, Calif.), the AIX UNIX operating system distributed by International Business Machines of Armonk, New York, the Linux operating system, the Mac OS X and iOS operating systems distributed by Apple Inc. of Cupertino, Calif., the BlackBerry OS distributed by Research In Motion of Waterloo, Canada, and the Android operating system developed by the Open Handset Alliance.

Computing devices, such as the controllers, biometric devices, displays, telematics functions, etc., may generally include computer-executable instructions that may be executable by one or more processors. Computer-executable instructions may be compiled or interpreted from computer programs created using a variety of programming languages and/or technologies, including, without limitation, and either alone or in combination, Java™, C, C++, Visual Basic, Java Script, Perl, etc. In general, a processor or microprocessor receives instructions, e.g., from a memory or a computer-readable medium, etc., and executes these instructions, thereby performing one or more processes, including one or more of the processes described herein. Such instructions and other data may be stored and transmitted using a variety of computer-readable media.

A computer-readable medium (also referred to as a processor-readable medium) includes any non-transitory (e.g., tangible) medium that participates in providing data (e.g., instructions) that may be read by a computer (e.g., by a processor of a computing device). Such a medium may take many forms, including, but not limited to, non-volatile media and volatile media. Non-volatile media may include, for example, optical or magnetic disks and other persistent memory. Volatile media may include, for example, dynamic random access memory (DRAM), which typically constitutes a main memory. Such instructions may be transmitted by one or more transmission media, including coaxial cables, copper wire and fiber optics, including the wires that comprise a system bus coupled to a processor of a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

Databases, data repositories or other data stores described herein may include various kinds of mechanisms for storing, accessing, and retrieving various kinds of data, including a hierarchical database, a set of files in a file system, an application database in a proprietary format, a relational database management system (RDBMS), etc. Each such data store is generally included within a computing device employing a computer operating system such as one of those mentioned above, and are accessed via a network in any one or more of a variety of manners. A file system may be accessible from a computer operating system, and may include files stored in various formats. An RDBMS generally employs the Structured Query Language (SQL) in addition to a language for creating, storing, editing, and executing stored procedures, such as the PL/SQL language mentioned above.

In some examples, system elements may be implemented as computer-readable instructions on one or more computing devices, stored on computer readable media associated therewith. A computer program product may comprise such instructions stored on computer readable media for carrying out the functions described herein. In some examples, the application software products may be provided as software that when executed by processors of the devices and servers provides the operations described herein. Alternatively, the application software product may be provided as hardware or firmware, or combinations of software, hardware and/or firmware.

What is claimed as new and desired to be protected by Letters Patent of the United States is:

1. A system comprising:
at least one sensor configured to detect at least one vital signal, wherein the sensor is positioned proximate to a driver within a vehicle seat;
at least one contact element configured to detect at least one reference signal, wherein the contact element surrounds a vehicle steering wheel; and
at least one resistor coupled to the at least one sensor and configured to receive the reference signal from the contact element.

2. The system of claim 1, wherein the reference signal is compared with the vital signal to produce a biometric signal.

3. The system of claim 2, wherein the biometric signal is a difference between the vital signal and the reference signal.

4. The system of claim 2, further comprising an amplifier configured to amplify the biometric signal.

5. The system of claim 2, further comprising an Electrical Control Unit (ECU) configured to process the biometric signal.

6. The system of claim 1, wherein the at least one sensor is a capacitive sensor and wherein the contact element is a direct contact sensor.

7. The system of claim 1, wherein the contact element surrounds the entire steering wheel.

8. The system of claim 1, wherein the at least one sensor is configured to detect electrical impulses from the driver.

9. The system of claim 1, wherein the reference signal includes an electrical potential of the driver.

10. The system of claim 1, wherein the at least one sensor includes a plurality of capacitive sensors.

11. The system of claim 1 wherein the at least one sensor includes a plurality of Electric Potential Sensors (EPS).

12. The system of claim 1, wherein the contact element includes a conductive fabric.

13. A sensor module, comprising:
a plurality of sensors configured to detect at least one vital signal, wherein the sensors are positioned proximate to a driver within a vehicle seat; and
a resistor coupled to each of the sensors and configured to receive a reference signal transmitted from a contact element having direct contact with the driver.

14. The sensor module of claim 13, wherein the contact element surrounds a vehicle steering wheel.

15. The sensor module of claim 13, wherein the reference signal is compared with the vital signal at each resistor to produce a biometric signal.

16. The sensor module of claim 15, wherein the biometric signal is a difference between the vital signal and the reference signal.

17. The sensor module of claim 15, further comprising an amplifier configured to amplify the biometric signal.

18. The sensor module of claim 15, further comprising an Electrical Control Unit (ECU) configured to process the biometric signal.

19. The sensor module of claim 13, wherein the sensors are configured to detect electrical impulses from the driver and wherein the reference signal includes an electrical potential of the driver.

20. The sensor module of claim 13, further comprising a signal conditioner configured to condition the at least one vital signal prior to comparing the at least one vital signal with the reference signal.
